(19) United States
(12) Patent Application Publication
(10) Pub. No.: US 2025/0349678 A1
(43) Pub. Date: Nov. 13, 2025

(54) LEAD FRAME AND MANUFACTURING METHOD OF ELECTRONIC PACKAGE USING THE SAME

(71) Applicant: SILICONWARE PRECISION INDUSTRIES CO., LTD., Taichung City (TW)

(72) Inventors: Perng-Wei CHEN, Taichung City (TW); Chien-Ting CHEN, Taichung City (TW); Chin-Wen LAI, Taichung City (TW)

(73) Assignee: SILICONWARE PRECISION INDUSTRIES CO., LTD., Taichung City (TW)

(21) Appl. No.: 18/794,660

(22) Filed: Aug. 5, 2024

(30) Foreign Application Priority Data
May 9, 2024 (TW) 113117234

(51) Int. Cl. H01L 23/495; H01L 21/56; H01L 23/00

(52) U.S. Cl. CPC H01L 23/49548; H01L 21/56; H01L 23/49503; H01L 23/562; H01L 24/48; H01L 2224/48227; H01L 2924/1815

(57) ABSTRACT

A lead frame is provided and includes: a die pad; and a plurality of connecting pads provided around the die pad, and bottom surfaces of at least a portion of the connecting pads are formed with metallic protective pads, each of the metallic protective pads is defined with a connecting reserved area and a processing area around the connecting reserved area, and the metallic protective pads and the connecting pads are made of different materials. By the implementation of the lead frame, the shape and size of each contact of an electronic package made using the lead frame technology are without errors caused by the different etching rates along a direction perpendicular to a forming direction and along a direction parallel to the forming direction, thereby avoiding problems such as poor contact due to the errors in the shapes and the sizes of the contacts.

### BACKGROUND

### 1. Technical Field

The present disclosure relates to a semiconductor device and a manufacturing method, and more particularly, to a lead frame for semiconductor element and a manufacturing method of an electronic package using the lead frame.

### 2. Description of Related Art

In recent years, electronic product designs are becoming thinner and smaller, but the number of input/output (I/O) points of semiconductor elements used therein has increased significantly due to design requirements. However, the manufacturing costs are required to be gradually reduced. Since the packaging structure and technology using lead frames are relatively cheap, they are still widely used today. Semiconductor packages that traditionally use lead frames as chip carriers, such as semiconductor packages with Quad Flat Package (QFP) or semiconductor packages with Quad Flat Non-leaded (QFN), etc. are produced in a manner that first provides a lead frame with a die pad and a plurality of leads. Each lead end of the lead frame is respectively provided with a connecting pad, and a protective layer with a metal having better chemical resistance is formed on bottom surfaces of at least a portion of the connecting pads and then is rolled and flattened. Then, a semiconductor chip is bonded to the die pad of the lead frame, and each pad on the semiconductor chip is electrically connected to a connecting pad of the corresponding lead end with a gold wire, and the chip and the gold wires are encapsulated by an encapsulant but the die pad and the bottom surfaces of the plurality of leads are exposed. Then, the middle part of each lead is removed by process such as chemical etching, remaining only the connecting pads at the lead ends and the protective layer on the bottom surfaces thereof as contacts for connecting the final product of the electronic package to external circuits in practical applications.

However, when the lead frame is etched in the above-mentioned process using the conventional lead frame, the etching rate along the forming direction where the protective layer is flattened will be slower than the etching rate perpendicular to the forming direction of the protective layer, resulting in the shape and size of the contacts left after etching are different from the originally designed shape and size. As a result, the finished electronic package cannot be correctly positioned and connected to the corresponding external circuit due to incorrect shape and size of the contacts during actual application, resulting in poor contact or even failure to conduct.

Therefore, there is a need for addressing the aforementioned shortcomings in the prior art.

### SUMMARY

In view of the aforementioned shortcomings of the prior art, the present disclosure

provides a lead frame, which comprises: a die pad; and a plurality of connecting pads provided around the chip die, wherein bottom surfaces of at least a portion of the connecting pads are formed with metallic protective pads, each of the metallic protective pads is defined with a connecting reserved area and a processing area surrounding the connecting reserved area, and the metallic protective pads and the plurality of connecting pads are made of different materials.

In the aforementioned lead frame, the lead frame is defined with a forming direction, and the metallic protective pads are flattened along the forming direction.

In the aforementioned lead frame, a width of the processing area of each of the metallic protective pads perpendicular to the forming direction is greater than a width of the processing area parallel to the forming direction.

In the aforementioned lead frame, the connecting reserved area of each of the metallic protective pads is rectangular, and long sides of the connecting reserved areas are perpendicular to an edge of one side of the lead frame where the metallic protective pads are located.

In the aforementioned lead frame, the width of the processing area of each of the metallic protective pads perpendicular to the forming direction is 1 to 1.23 times the width of the processing area parallel to the forming direction.

In the aforementioned lead frame, the connecting reserved area of each of the metallic protective pads is rectangular, and long sides of the connecting reserved areas are parallel to an edge of one side of the lead frame where the metallic protective pads are located.

In the aforementioned lead frame, the width of the processing area of each of the metallic protective pads perpendicular to the forming direction is 1 to 1.23 times the width of the processing area parallel to the forming direction.

In the aforementioned lead frame, the connecting reserved area of each of the metallic protective pads is rectangular, and long sides of a portion of the metallic protective pads are perpendicular to an edge of one side of the lead frame where the metallic protective pads are located, and long sides of another portion of the metallic protective pads are parallel to the edge of the one side of the lead frame where the metallic protective pads are located.

In the aforementioned lead frame, the width of the processing area of each of the metallic protective pads perpendicular to the forming direction is 1 to 1.23 times the width of the processing area parallel to the forming direction.

In the aforementioned lead frame, the connecting reserved area of each of the metallic protective pads has a circular shape.

In the aforementioned lead frame, the width of the processing area of each of the metallic protective pads perpendicular to the forming direction is 1 to 1.15 times the width of the processing area parallel to the forming direction.

The present disclosure also provides a method of manufacturing an electronic

package, and the method comprises: providing the aforementioned lead frame of any type; bonding an electronic element on the die pad of the lead frame; electrically connecting the electronic element and the connecting pads of the lead frame via a plurality of wires; encapsulating the electronic element and the plurality of wires with a packaging material; and removing the processing area of each of the metallic protective pads.

In the aforementioned method, the present disclosure further comprises forming a protective layer on a lower surface of each of the connecting pads that is without the metallic protective pad after removing the processing area of each of the metallic protective pads.

As can be understood from the above, in the lead frame and manufacturing method of the electronic package using the lead frame of the present disclosure, the shape and size of each contact of the electronic package made using the relatively cheap lead frame technology are prevented from errors caused by different rates of etching and other processes along the forming direction perpendicular to the lead frame and the forming direction parallel to the lead frame, thereby avoiding problems such as poor contact during use of electronic package due to errors in the shape and size of the contact.

### BRIEF DESCRIPTION OF THE DRAWINGS

FIG. 1A to FIG. 1E are schematic diagrams of embodiments of the manufacturing method of the electronic package of the present disclosure.

FIG. 2A to FIG. 2D are schematic bottom views of different aspects of the lead frame embodiment of the present disclosure.

FIG. 3A-1 to FIG. 3A-2 are partial enlarged schematic views of the bottom side of the metallic protective pad in FIG. 2A to FIG. 2C.

FIG. 3B is a partial enlarged schematic view of the bottom side of the metallic protective pad in FIG. 2D.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

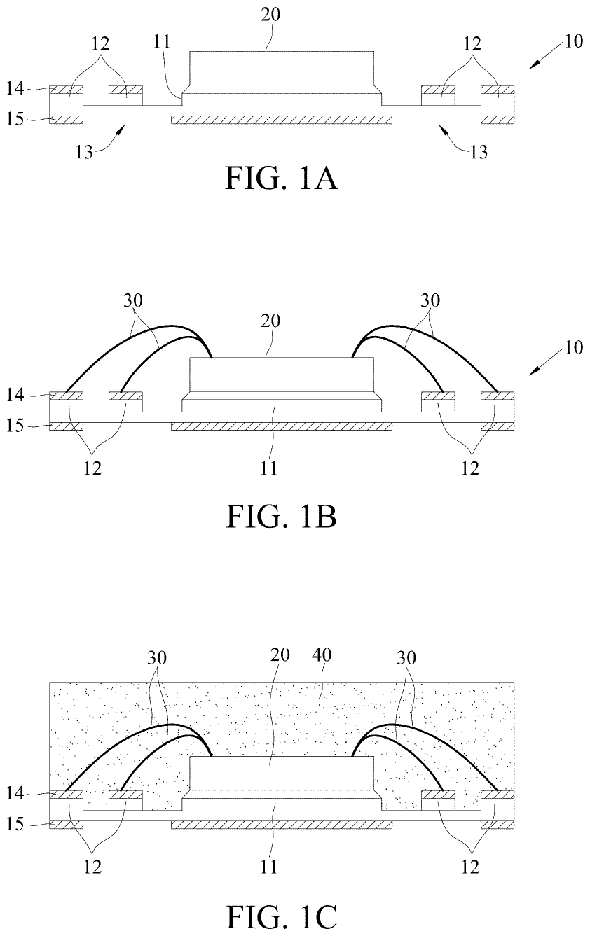

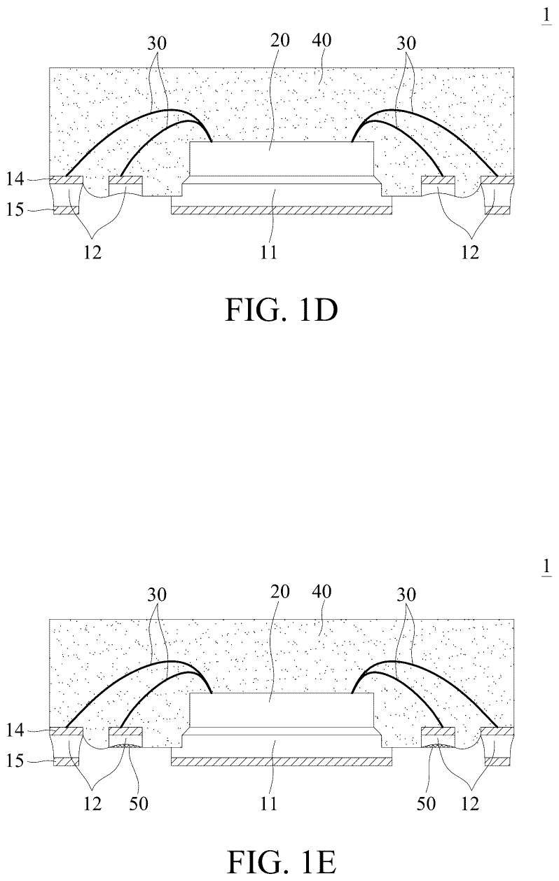

FIG. 1A to FIG. 1E are schematic diagrams of embodiments of the manufacturing method of the electronic package of the present disclosure.

In an embodiment, as shown in FIG. 1A to FIG. 1E, a method of manufacturing an electronic package is disclosed. The manufacturing method first provides a lead frame 10 as shown in FIG. 1A. Please refer to FIG. 2A and FIG. 3A-1 at the same time. The lead frame 10 includes a die pad 11 and a plurality of connecting pads 12 surrounding the die pad 11. The bottom surfaces of at least a portion of the connecting pads 12 are formed with metallic protective pads 15 that are in close contact with the connecting pads 12 and electrically connected thereto. Each metallic protective pad 15 is defined with a connecting reserved area 15a and a processing area 15b surrounding the connecting reserved area 15a. The die pad 11 and the plurality of connecting pads 12 are made of the same conductive material, while the metallic protective pad 15 is made of a different conductive material. Generally, the die pad 11 is usually connected to the connecting pads 12 via a plurality of structures such as connecting arms 13 to fix the connecting pads 12 around the die pad 11. The die pad 11, the connecting arms 13 and the connecting pads 12 are usually made of metal with better conductivity and better processability, such as copper-containing alloy. The metallic protective pad 15 is made of a metal with better chemical resistance, such as nickel (Ni), palladium (Pd), gold (Au), etc., or an alloy of any two or more of them.

The metallic protective pad 15 is defined with a forming direction D_{f}. The forming direction D_{f} is the direction in which the metallic protective pad 15 is flattened during the process of being formed on the bottom surface of the connecting pad 12. More specifically, the forming direction D_{f} is the direction in which the metallic protective pad 15 is rolled and flattened, or the direction in which the crystal structure of the material of the metallic protective pad 15 is forced when it is rolled and flattened. The processing area 15b of the metallic protective pad 15 on the bottom side of the connecting pad 12 is formed to have a width perpendicular to the forming direction D_{f} that is greater than a width parallel to the forming direction D_{f}. In some different embodiments, in addition to forming metallic protective pads 15 on the bottom surfaces of the connecting pads 12, metallic protective pads 14 may also be formed on the top surfaces of some connecting pads 12 as required, but the present disclosure is not limited to as such.

Then, an electronic element 20 (such as a semiconductor die) is bonded to the die pad 11 of the lead frame 10.

Then, as shown in FIG. 1B, the electronic element 20 is connected to the connecting pads 12 of the lead frame 10 by a plurality of wires 30, allowing each connecting pad 12 to be electrically connected to a contact (not shown) on the electronic element 20 respectively. The wire 30 is, for example, a gold wire, but may also be a wire made of any other suitable conductive material. Next, as shown in FIG. 1C, a packaging layer 40 made of a packaging material is formed and encapsulates the electronic element 20, the wires 30 and the lead frame 10.

As shown in FIG. 1D, each connecting arm 13, part of each connecting pad 12 and the processing area 15b of each metallic protective pad 15 are removed by, for example, chemical etching, remaining the connecting pads 12 partially etched and the connecting reserved areas 15a of the metallic protective pads 15, and thus a multi row quad flat non-leaded (MR-QFN) type electronic package 1 can be obtained.

In the above process of removing each connecting arm 13, part of each connecting pad 12 and the processing area 15b of each metallic protective pad 15, since each metallic protective pad 15 has a processing area 15b outside the connecting reserved area 15a, and a width of the processing area 15b of each metallic protective pad 15 perpendicular to a forming direction D_{f} is greater than a width of the processing area 15b parallel to the forming direction D_{f}; therefore, even though the etching rate along a direction parallel to the forming direction D_{f} is slower than the etching rate along a direction perpendicular to the forming direction D_{f}, the processing area 15b of each metallic protective pad 15 can still be accurately removed after the etching is completed, remaining only the connecting reserved area 15a of which the shape and size is comply to the design.

As shown in FIG. 1E, in some preferred embodiments, after removing the processing area 15b of each metallic protective pad 15, a protective layer 50 can be further formed on the lower surface of the connecting pad 12 (as a circuit) that has no metallic protective pad 15. A material of the protective layer 50 is, for example, a solder-resist material such as solder-resist paint, but the present disclosure is not limited to as such.

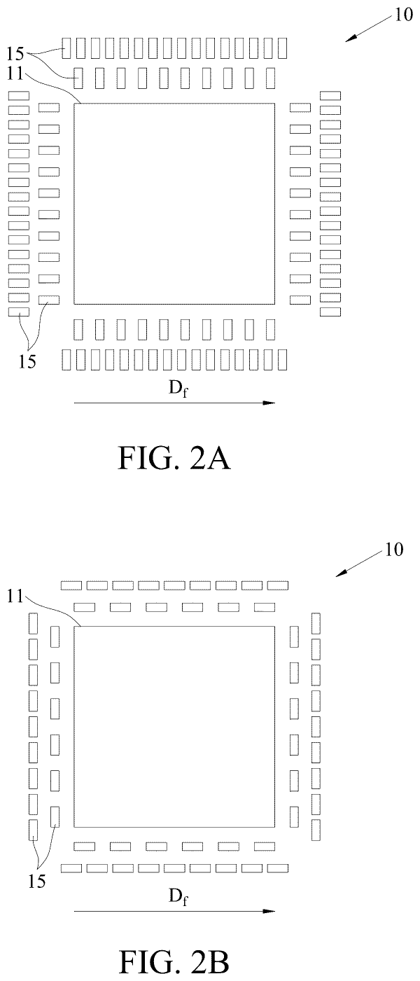

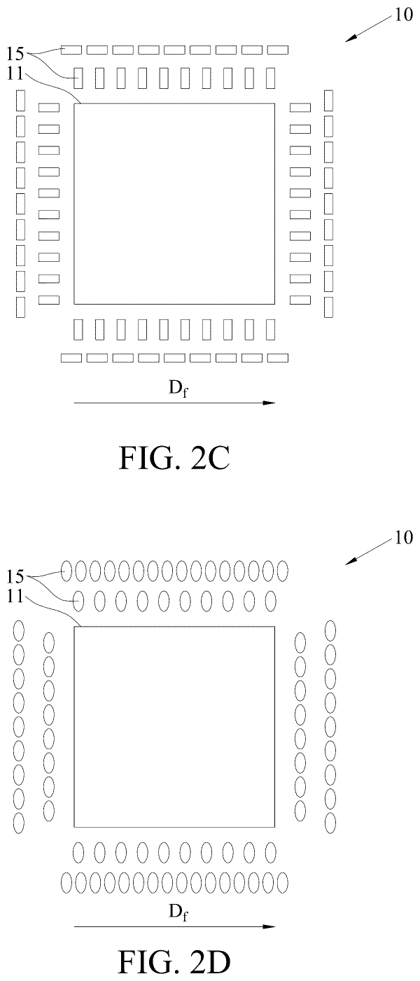

In an embodiment, in the manufacturing method of the electronic package, the metallic protective pad 15 and the connecting reserved area 15a thereof can have different shapes. For example, as some embodiments shown in FIG. 2A, the connecting reserved area 15a of each metallic protective pad 15 is rectangular, and a long side thereof is perpendicular to an edge of one side of the lead frame 10 where the metallic protective pad 15 is located.

Please refer to FIG. 3A-1 and FIG. 3A-2 at the same time, in an embodiment, the width of the processing area 15b of each metallic protective pad 15 perpendicular to the forming direction D_{f} is 1 to 1.23 times the width of the processing area 15b parallel to the forming direction D_{f}.

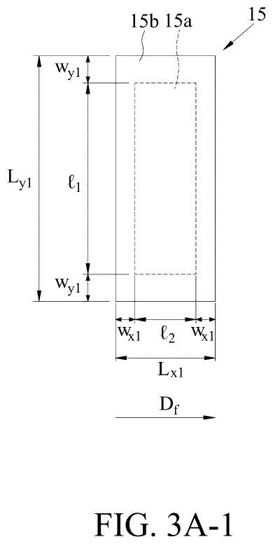

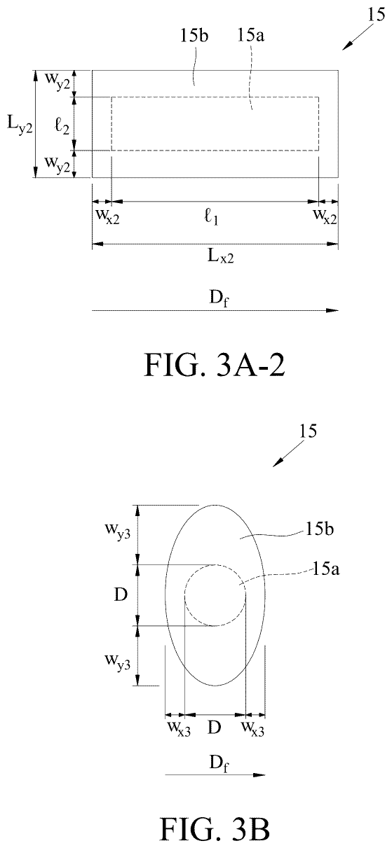

More specifically, in an aspect, the shape of each metallic protective pad 15 located on the upper and lower sides of the die pad 11 in FIG. 2A is shown in FIG. 3A-1. The width of the processing area 15b located on the left and right sides of the connecting reserved area 15a of the metallic protective pad 15 is wₓ₁, and the width of the processing area 15b located on the upper and lower sides of the connecting reserved area 15a is w_{y1}. The shape of each metallic protective pad 15 located on the left and right sides of the die pad 11 in FIG. 2A is as shown in FIG. 3A-2. The width of the processing area 15b located on the left and right sides of the connecting reserved area 15a of the metallic protective pad 15 is wₓ₂, and the width of the processing area 15b located on the upper and lower sides of the connecting reserved area 15a is w_{y2}. For the metallic protective pads 15 on the upper and lower sides of the die pad 11 in FIG. 2A, wₓ₂≤w_{y1}≤1.23wₓ₂, that is, w_{y1} is 1 to 1.23 times the wₓ₂, and the full length of the long side of the metallic protective pad 15 is L_{y1}=l₁+2w_{y1}, and the full length of the short side thereof is Lₓ₁=l₂+2wₓ₁. For the metallic protective pads 15 on the left and right sides of the die pad 11 in FIG. 2A, wₓ₁≤w_{y2}≤1.23wₓ₁, that is, w_{y2} is also 1 to 1.23 times the wₓ₁, and the full length of the long side of the metallic protective pad 15 is Lₓ₂=l₁+2wₓ₂, and the full length of the short side thereof is L_{y2}=l₂+2w_{y2}. In other words, before etching, the metallic protective pads 15 located on the upper and lower sides of the die pad 11 are different in size from the metallic protective pads 15 located on the left and right sides of the die pad 11. However, no matter which sides of the die pad 11 that the connecting reserved area 15a is remained after the etching is completed, the connecting reserved area 15a will be a rectangle with the long side being l₁ long and the short side being 12 long.

Similarly, in an embodiment shown in FIG. 2B, the connecting reserved area 15a of each metallic protective pad 15 is also rectangular with long side parallel to an edge of one side of the lead frame 10 where the metallic protective pad 15 is located. In an embodiment, the size arrangement of the metallic protective pads 15 located on the upper and lower sides of the die pad 11 is shown in FIG. 3A-2, and the size arrangement of the metallic protective pads 15 located on the left and right sides of the die pad 11 is shown in FIG. 3A-1, but the width of the processing area 15b of each metallic protective pad 15 perpendicular to the forming direction D_{f} is still 1 to 1.23 times the width of the processing area 15b parallel to the forming direction D_{f}, and the remaining connecting reserved area 15a after etching will be a rectangle with the long side being l₁ long and the short side being l₂ long.

Alternatively, the metallic protective pads 15 can also be disposed as shown in FIG. 2C. The connecting reserved area 15a of each metallic protective pad 15 is also rectangular, but the long sides of a portion of the metallic protective pads 15 are perpendicular to the edge of one side of the lead frame 10 where the metallic protective pads 15 are located, and the long sides of another portion of the metallic protective pads 15 are parallel to the edge of one side of the lead frame 10 where the metallic protective pads 15 are located. Even so, the width of the processing area 15b of each metallic protective pad 15 perpendicular to the forming direction D_{f} is still 1 to 1.23 times the width of the processing area 15b parallel to the forming direction D_{f}.

In addition to the rectangular shape, the connecting reserved area 15a of each metallic protective pad 15 can also be circular as shown in FIG. 2D. In an embodiment, the shape and size arrangement of each metallic protective pad 15 is as shown in FIG. 3B, and the connecting reserved area 15a thereof is a circle with a diameter D. The width w_{y3} of the processing area 15b perpendicular to the forming direction D_{f} is 1 to 1.15 times the width wₓ₃ of the processing area 15b parallel to the forming direction D_{f}. In this way, the remaining connecting reserved area 15a after etching is a circle with a diameter D.

The present disclosure also discloses a lead frame 10, which comprises: a die pad 11; and a plurality of connecting pads 12 arranged around the die pad 11. The bottom surfaces of at least a portion of the connecting pads 12 are formed with metallic protective pads 15, and each of the metallic protective pads 15 is defined with a connecting reserved area 15a and a processing area 15b surrounding the connecting reserved area 15a, and the metallic protective pads 15 and the plurality of connecting pads 12 are made of different materials. The lead frame 10 and its various implementation aspects are the same as those used and illustrated in the above-mentioned embodiments of the manufacturing method of the electronic package, so the details will not be repeated here.

In view of the above, the manufacturing method of the electronic package and the lead frame used in the manufacturing method can ensure that the shape and size of each contact of the electronic package are prevented from errors caused by different rates of etching and other processes along the forming direction perpendicular to the metallic protective pad and the forming direction parallel to the metallic protective pad, thereby avoiding problems such as poor contact during use of electronic package due to errors in the shape and size of the contact.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A lead frame, comprising:
a die pad; and
a plurality of connecting pads provided around the chip die, wherein bottom surfaces of at least a portion of the connecting pads are formed with metallic protective pads, each of the metallic protective pads is defined with a connecting reserved area and a processing area surrounding the connecting reserved area, and the metallic protective pads and the plurality of connecting pads are made of different materials.

2. The lead frame of claim 1, wherein the lead frame is defined with a forming direction, and the metallic protective pads are flattened along the forming direction.

3. The lead frame of claim 2, wherein a width of the processing area of each of the metallic protective pads perpendicular to the forming direction is greater than a width of the processing area parallel to the forming direction.

4. The lead frame of claim 3, wherein the connecting reserved area of each of the metallic protective pads is rectangular, and long sides of the connecting reserved areas are perpendicular to an edge of one side of the lead frame where the metallic protective pads are located.

5. The lead frame of claim 4, wherein the width of the processing area of each of the metallic protective pads perpendicular to the forming direction is 1 to 1.23 times the width of the processing area parallel to the forming direction.

6. The lead frame of claim 3, wherein the connecting reserved area of each of the metallic protective pads is rectangular, and long sides of the connecting reserved areas are parallel to an edge of one side of the lead frame where the metallic protective pads are located.

7. The lead frame of claim 6, wherein the width of the processing area of each of the metallic protective pads perpendicular to the forming direction is 1 to 1.23 times the width of the processing area parallel to the forming direction.

8. The lead frame of claim 3, wherein the connecting reserved area of each of the metallic protective pads is rectangular, and long sides of a portion of the metallic protective pads are perpendicular to an edge of one side of the lead frame where the metallic protective pads are located, and long sides of another portion of the metallic protective pads are parallel to the edge of the one side of the lead frame where the metallic protective pads are located.

9. The lead frame of claim 8, wherein the width of the processing area of each of the metallic protective pads perpendicular to the forming direction is 1 to 1.23 times the width of the processing area parallel to the forming direction.

10. The lead frame of claim 3, wherein the connecting reserved area of each of the metallic protective pads has a circular shape.

11. The lead frame of claim 10, wherein the width of the processing area of each of the metallic protective pads perpendicular to the forming direction is 1 to 1.15 times the width of the processing area parallel to the forming direction.

12. A method of manufacturing an electronic package, comprising:
providing the lead frame of claim 1;
bonding an electronic element on the die pad of the lead frame;
electrically connecting the electronic element and the connecting pads of the lead frame via a plurality of wires;
encapsulating the electronic element and the plurality of wires with a packaging material; and
removing the processing area of each of the metallic protective pads.

13. The method of claim 12, further comprising forming a protective layer on a lower surface of each of the connecting pads that is without the metallic protective pad after removing the processing area of each of the metallic protective pads.

14. A method of manufacturing an electronic package, comprising:
providing the lead frame of claim 2;
bonding an electronic element on the die pad of the lead frame;
electrically connecting the electronic element and the connecting pads of the lead frame via a plurality of wires;
encapsulating the electronic element and the plurality of wires with a packaging material; and
removing the processing area of each of the metallic protective pads.

15. The method of claim 14, further comprising forming a protective layer on a lower surface of each of the connecting pads that is without the metallic protective pad after removing the processing area of each of the metallic protective pads.

16. A method of manufacturing an electronic package, comprising:
providing the lead frame of claim 3;
bonding an electronic element on the die pad of the lead frame;
electrically connecting the electronic element and the connecting pads of the lead frame via a plurality of wires;
encapsulating the electronic element and the plurality of wires with a packaging material; and
removing the processing area of each of the metallic protective pads.

17. The method of claim 16, further comprising forming a protective layer on a lower surface of each of the connecting pads that is without the metallic protective pad after removing the processing area of each of the metallic protective pads.

18. A method of manufacturing an electronic package, comprising:
providing the lead frame of claim 4;
bonding an electronic element on the die pad of the lead frame;
electrically connecting the electronic element and the connecting pads of the lead frame via a plurality of wires;
encapsulating the electronic element and the plurality of wires with a packaging material; and
removing the processing area of each of the metallic protective pads.

19. The method of claim 18, further comprising forming a protective layer on a lower surface of each of the connecting pads that is without the metallic protective pad after removing the processing area of each of the metallic protective pads.

20. A method of manufacturing an electronic package, comprising:
providing the lead frame of claim 5;
bonding an electronic element on the die pad of the lead frame;
electrically connecting the electronic element and the connecting pads of the lead frame via a plurality of wires;
encapsulating the electronic element and the plurality of wires with a packaging material; and
removing the processing area of each of the metallic protective pads.

21. The method of claim 20, further comprising forming a protective layer on a lower surface of each of the connecting pads that is without the metallic protective pad after removing the processing area of each of the metallic protective pads.

22. A method of manufacturing an electronic package, comprising:
providing the lead frame of claim 6;
bonding an electronic element on the die pad of the lead frame;
electrically connecting the electronic element and the connecting pads of the lead frame via a plurality of wires;
encapsulating the electronic element and the plurality of wires with a packaging material; and
removing the processing area of each of the metallic protective pads.

23. The method of claim 22, further comprising forming a protective layer on a lower surface of each of the connecting pads that is without the metallic protective pad after removing the processing area of each of the metallic protective pads.

24. A method of manufacturing an electronic package, comprising:
providing the lead frame of claim 7;
bonding an electronic element on the die pad of the lead frame;
electrically connecting the electronic element and the connecting pads of the lead frame via a plurality of wires;
encapsulating the electronic element and the plurality of wires with a packaging material; and
removing the processing area of each of the metallic protective pads.

25. The method of claim 24, further comprising forming a protective layer on a lower surface of each of the connecting pads that is without the metallic protective pad after removing the processing area of each of the metallic protective pads.

26. A method of manufacturing an electronic package, comprising:
providing the lead frame of claim 8;
bonding an electronic element on the die pad of the lead frame;
electrically connecting the electronic element and the connecting pads of the lead frame via a plurality of wires;
encapsulating the electronic element and the plurality of wires with a packaging material; and
removing the processing area of each of the metallic protective pads.

27. The method of claim 26, further comprising forming a protective layer on a lower surface of each of the connecting pads that is without the metallic protective pad after removing the processing area of each of the metallic protective pads.

28. A method of manufacturing an electronic package, comprising:
providing the lead frame of claim 9;
bonding an electronic element on the die pad of the lead frame;
electrically connecting the electronic element and the connecting pads of the lead frame via a plurality of wires;
encapsulating the electronic element and the plurality of wires with a packaging material; and
removing the processing area of each of the metallic protective pads.

29. The method of claim 28, further comprising forming a protective layer on a lower surface of each of the connecting pads that is without the metallic protective pad after removing the processing area of each of the metallic protective pads.

30. A method of manufacturing an electronic package, comprising:
providing the lead frame of claim 10;
bonding an electronic element on the die pad of the lead frame;
electrically connecting the electronic element and the connecting pads of the lead frame via a plurality of wires;
encapsulating the electronic element and the plurality of wires with a packaging material; and
removing the processing area of each of the metallic protective pads.

31. The method of claim 30, further comprising forming a protective layer on a lower surface of each of the connecting pads that is without the metallic protective pad after removing the processing area of each of the metallic protective pads.

32. A method of manufacturing an electronic package, comprising:
providing the lead frame of claim 11;
bonding an electronic element on the die pad of the lead frame;
electrically connecting the electronic element and the connecting pads of the lead frame via a plurality of wires;
encapsulating the electronic element and the plurality of wires with a packaging material; and
removing the processing area of each of the metallic protective pads.

33. The method of claim 32, further comprising forming a protective layer on a lower surface of each of the connecting pads that is without the metallic protective pad after removing the processing area of each of the metallic protective pads.
